(19) United States
(12) Patent Application Publication
(10) Pub. No.: US 2011/0132758 A1
(43) Pub. Date: Jun. 9, 2011

(54) STRUCTURE FOR INCREASING UTILIZATION RATE OF TARGET

(75) Inventors: Kang-Feng Lee, Hsinchu County (TW); Kuan-Chou Chen, Hsinchu City (TW); Muh-Wang Liang, Miaoli County (TW); Chian-Fu Huang, Keelung City (TW)

(73) Assignee: INDUSTRIAL TECHNOLOGY RESEARCH INSTITUTE, Hsinchu (TW)

(21) Appl. No.: 12/717,667

(22) Filed: Mar. 4, 2010

(30) Foreign Application Priority Data
Dec. 4, 2009 (TW) 098141490

(51) Int. Cl. C23C 14/35

(52) U.S. Cl. 204/298.16

(57) ABSTRACT

A structure for increasing utilization rate of target is disclosed, which comprises: a magnetic base, capable of moving relative to a target in a reciprocating manner; and two magnetic conductors, disposed respectively at two motion limits with respect to the reciprocating range of the magnetic base. Thereby, when the magnetic base is moved to a position close to any one of magnetic conductors, the surface magnetic field intensity of the target that is caused by the magnetic base is reduced so that the ion bombardment happening at the two ends of the target will be eased off for increasing the utilization rate of the target.

### TECHNICAL FIELD

The present disclosure relates to a magnetron sputtering deposition process, and more particularly, to a structure capable of adjusting its intensity distributions of magnetic field and the magnetic circuits that are caused at the motion limits of its movable base so as to reduce the bombardment happening at such motion limits and thus increasing the utilization rate of the target.

### TECHNICAL BACKGROUND

Sputtering is a process whereby atoms are ejected from a solid target material due to bombardment of the target by energetic particles, such as ions excited in the plasma generated in the reaction chamber of sputtering device. It is commonly used for forming a thin film on a substrate surface by deposition.

Please refer to FIG. 1, which is a schematic diagram showing a conventional magnetron sputtering device with movable base. In FIG. 1, the sputtering device is primarily comprised of: a reaction chamber 81, a target 82, a magnetic base 83, a deck 84 and a substrate 85, in which after charged plasma ions are introduced into the vacuumed reaction chamber 81, those positively charged ions will be drawn to bombard the target 82 by the potential gradient between the target 82 and the deck that are caused as the target is connected to a cathode and the deck is connect to a anode, and thereby, atoms on the target 82 will be ejected and thus deposited on the surface of the substrate 85 so as to form a thin film thereon.

Since the magnetic base 83 is designed to move reciprocatively for scanning the back of the target 82, the intensity distribution of the magnetic field on the target that is caused by the magnetic base 83 will be varying with the scanning of the magnetic base 83, and thus the way relating to how the ions are going to bombard the target 82 will be changed accordingly which is going to affect the deposition rate of thin film on the substrate 85.

However, the aforesaid conventional magnetron sputtering device with movable base is advantageous in its low utilization rate of the target 82, that is, as the magnetic base 83 will be enabled to move in an opposite direction after it reaches it motion limit, the two portion of the target 82 relating to the motion limits of the magnetic base 83 will be bombarded more severely than the other portions, as shown in FIG. 2, so that the referring two portions of the target 82 will be exhausted before the other portions did and once they are exhausted by the bombardment, the target 82 will no longer be usable and must be replaced in the sputtering device whereas there is still plenty of target material left in the other portions.

It is noted that the improvement of conventional magnetron sputtering device is enforced only after the intensity distribution of magnetic field are detected and analyzed so as to be used as basis for determining how the magnets of different intensities are to be located or how a material of magnetic permeability are to be distributed. However, the locations of magnets or the distribution of magnetic-permeable material in a magnetron sputter has to be changed every time when the intensity of magnetic field has changed or when a different sputtering process with different sputtering conditions is required to be performed. Therefore, it is in need of an improvement that can overcome the aforesaid shortcomings

### TECHNICAL SUMMARY

The present disclosure is to provide a target structure capable of overcoming the aforesaid shortcomings by the arrangement of magnetic conductors respectively at two motion limits with respect to the reciprocating range of a magnetic base so as to enable a surface magnetic field intensity to reduce and thus increase the utilization rate of the target.

The present disclosure provides a structure for increasing utilization rate of target, which comprises: a magnetic base, capable of moving relative to a target in a reciprocating manner; and two magnetic conductors, disposed respectively at two motion limits with respect to the reciprocating range of the magnetic base.

In an embodiment of the present disclosure, the magnetic base further comprises: a frame, which is configured with a support seat at a side thereof adjacent to the target whereas the support seat is configured with a first polarity magnetic element and a plurality of second polarity magnetic elements in a manner that the first polarity magnetic element is arranged at the center of the support seat while arranging the second polarity magnetic elements surrounding the first polarity magnetic element in a ring-like formation.

In another embodiment, the two magnetic conductors are arranged at locations respectively between the target and a position under the outer sides the adjacent second polarity magnetic elements at the time when the magnetic base reaches its two motion limits. Nevertheless, in further another embodiment, the magnetic conductors are arranged at positions respectively adjacent to the second polarity magnetic elements at the time when the magnetic base reaches its two motion limits.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing a conventional magnetron sputtering device with movable base.

FIG. 2 is a schematic diagram showing the erosion at the two ends of a target that is caused by the bombardment a conventional sputtering device.

FIG. 3 is a schematic diagram showing a structure for increasing utilization rate of target according to a first embodiment of the present disclosure.

FIG. 4 is a three dimensional view of a magnetic base used in the structure of the present disclosure.

FIG. 5A shows a magnetic circuit resulting from a conventional magnetic base.

FIG. 5B shows a magnetic circuit resulting from a magnetic base of the present disclosure at the time when it approach to one of its magnetic conductors.

FIG. 6 is a chart comparing the variation of magnetic field intensity measured in the present disclosure with the one from prior arts.

FIG. 7 is a schematic diagram showing two different erosions at the two ends of a target that are caused respectively by the bombardment a conventional sputtering device and a sputtering device of the present disclosure.

FIG. 8 is a schematic diagram showing a multiple-target magnetron sputtering device using the structure of the present disclosure.

FIG. 9 is a schematic diagram showing a structure for increasing utilization rate of target according to a second embodiment of the present disclosure.

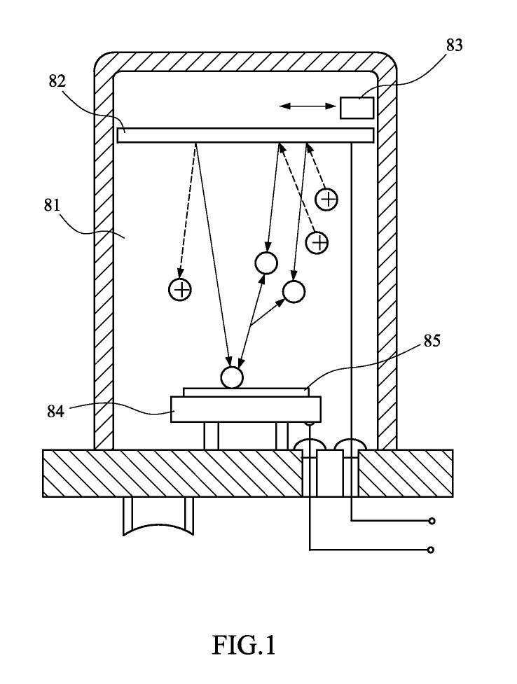

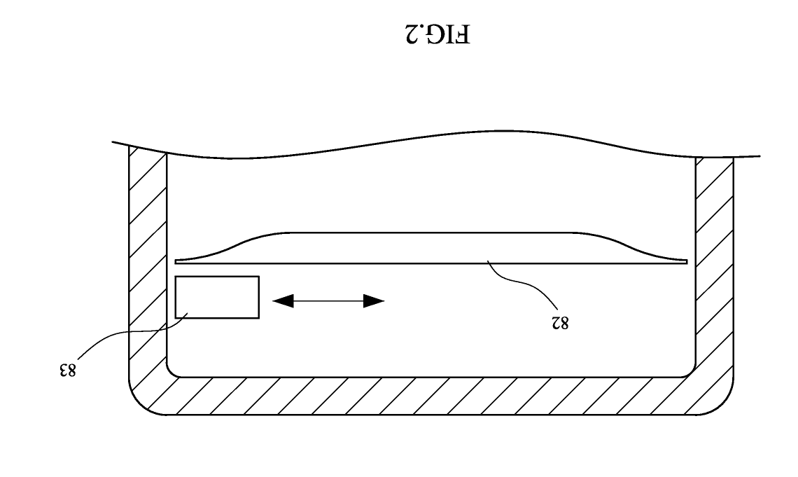

### DESCRIPTION OF THE EXEMPLARY EMBODIMENTS

For your esteemed members of reviewing committee to further understand and recognize the fulfilled functions and structural characteristics of the disclosure, several exemplary embodiments cooperating with detailed description are presented as the follows.

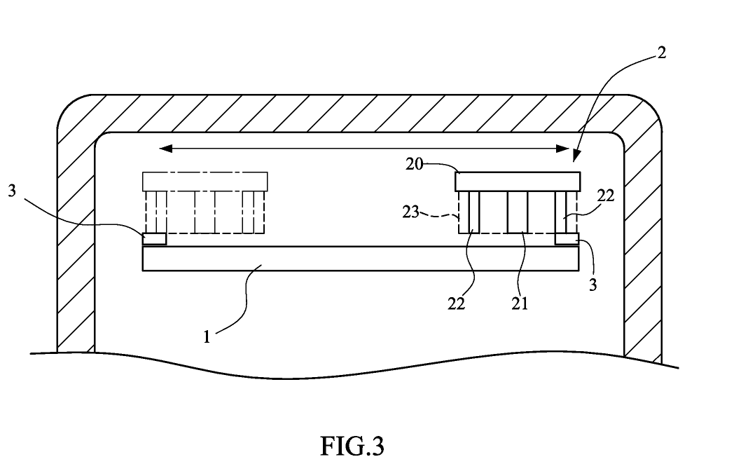

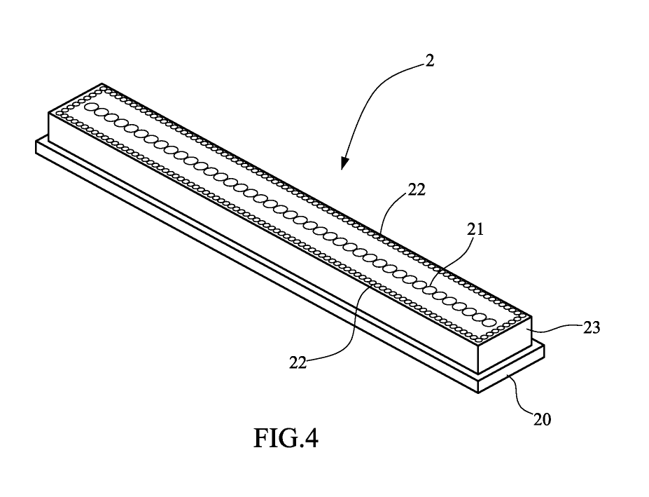

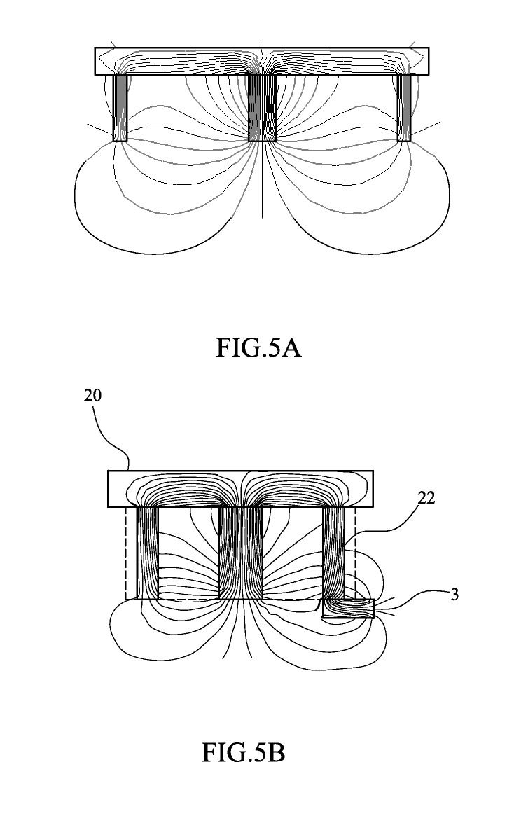

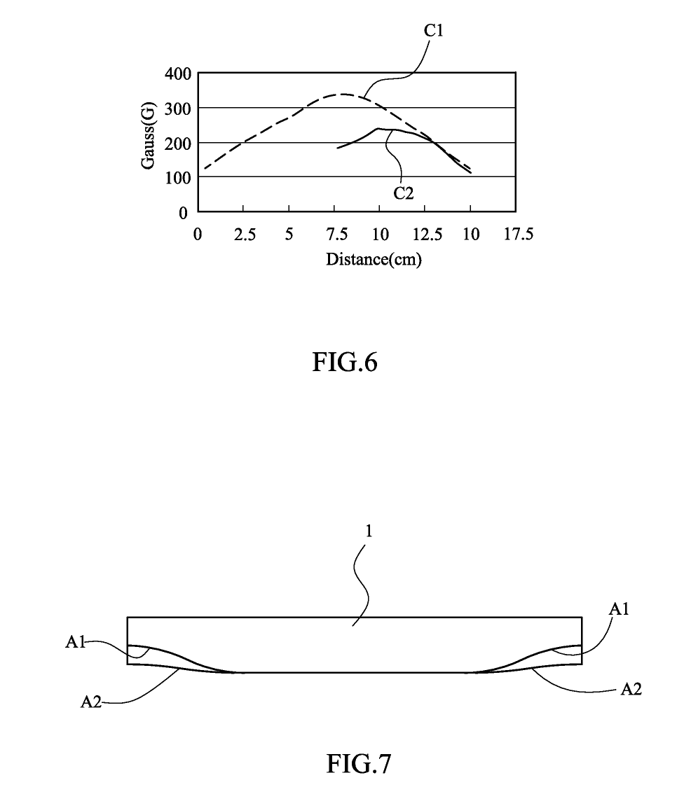

Please refer to FIG. 3 to FIG. 7, in which FIG. 3 is a schematic diagram showing a structure for increasing utilization rate of target according to a first embodiment of the present disclosure; FIG. 4 is a three dimensional view of a magnetic base used in the structure of the present disclosure; FIG. 5A shows a magnetic circuit resulting from a conventional magnetic base; FIG. 5B shows a magnetic circuit resulting from a magnetic base of the present disclosure at the time when it approach to one of its magnetic conductors; FIG. 6 is a chart comparing the variation of magnetic field intensity measured in the present disclosure with the one from prior arts; and FIG. 7 is a schematic diagram showing two different erosions at the two ends of a target that are caused respectively by the bombardment a conventional sputtering device and a sputtering device of the present disclosure.

It is noted that the structure for increasing utilization rate of target disclosed in the present disclosure can be adapted for single-target magnetron sputtering devices and multiple-target magnetron sputtering device. In those embodiment, a structure, being adapted for a single-target magnetron sputtering device, is used for illustration which comprises: a magnetic base 2, positioned over a target 1 while enabling the same to move relative to a target in a reciprocating manner; and two magnetic conductors 3, disposed respectively at two motion limits with respect to the reciprocating range of the magnetic base 2.

Moreover, the magnetic base 2 has a frame 20, which is configured with a first polarity magnetic element 21 and a plurality of second polarity magnetic elements 22 in a manner that the first polarity magnetic element 21 is arranged at the center of the frame 20 on the side thereof facing toward the target 1 while arranging the second polarity magnetic elements 22 surrounding the first polarity magnetic element in a ring-like formation. For fixing the first polarity magnetic element 21 and the plural second polarity magnetic elements 22, the frame 20 further has a support seat 23 mounted on the frame 20, that is provided for the first polarity magnetic element 21 and the second polarity magnetic elements to fixed thereat.

In this embodiment, the frame 20 is a rectangle-shaped object made of a magnetic conductive material; the first polarity magnetic element as well as each polarity magnetic element is made up of permanent magnets; the support seat is made of a non-magnetic conductive material; and each magnetic conductor is made of a material selected from the group consisting of: iron, cobalt, nickel and the alloys thereof. In addition, the two magnetic conductors 3 are arranged at locations respectively under the outer sides the adjacent second polarity magnetic elements 22 at the time when the magnetic base reaches its two motion limits for enabling the same to be sandwiched between the adjacent second polarity magnetic elements 22 and the target 1.

As shown in FIG. 5A and FIG. 5B, since the two magnetic conductors 3 are arranged at locations respectively between the target 1 and a position under the outer sides the adjacent second polarity magnetic elements 22 at the time when the magnetic base reaches its two motion limits, the magnetic lines will be subjected to the influence of the magnetic conductors 3 and thus being compressed as the magnetic base 2 is moving approaching the motion limits, so that the geometric shape of its magnetic circuit is changed accordingly.

By the compressing of magnetic lines and the changing of the corresponding magnetic circuit as the magnetic based 2 is moving approaching the motion limits and closing to the magnetic conductors 3, the surface magnetic field intensity of the target that is caused by the magnetic base 2 is weakened. As shown in FIG. 6, the curve C1 represents the relationship between distance and the variation of magnetic field intensity measured when there is no magnetic conductor as those in the prior-art sputtering devices and the curve C2 represents the relationship between distance and the variation of magnetic field intensity measured when there are magnetic conductors as that disclosure in the present disclosure. In FIG. 6, the prior-art device will reach its maximum magnetic field intensity of about 340 Gauss when the magnetic base reaches its motion limit, while the maximum magnetic field intensity of the present invention is only about 240 Gauss, which is a significant reduction.

As the magnetic field intensity on the target that is caused by the magnetic base 3 is reduced significantly at the time when the magnetic base 2 reaches its motion limits, the phenomenon, that the two portion of the target 1 relating to the motion limits of the magnetic base 2 will be bombarded more severely than the other portions as the magnetic base 2 is enabled to move back in an opposite direction after it reaches it motion limit, can be eased off significantly. As shown in FIG. 7, the curves A1 represent the erosion of the target 1 happened at the two ends thereof that are caused respectively by the bombardment a conventional sputtering device; and the curves A2 represent the erosion of the target 1 happened at the two ends thereof that are caused respectively by the bombardment a sputtering device of the present disclosure. By the comparison between the curves A1 and A2, it is obvious that the bombardment at the two ends of the target 1 had been eased off and thus the utilization rate of the target 1 is enhanced.

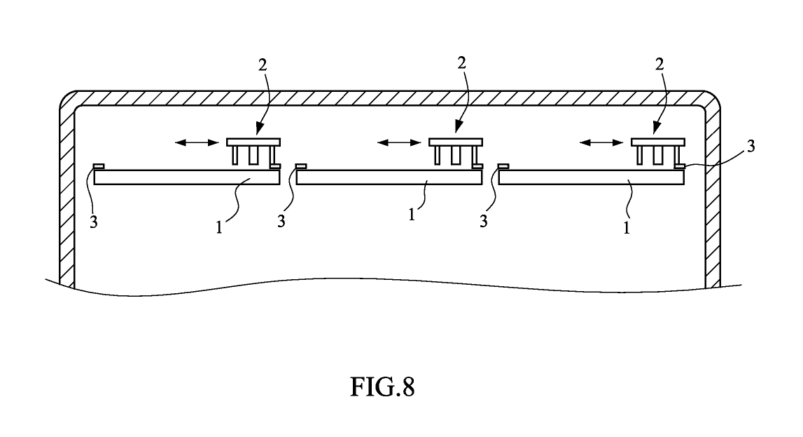

Please refer to FIG. 8, which is a schematic diagram showing a multiple-target magnetron sputtering device using the structure of the present disclosure. In FIG. 8, there are three targets 1 in the sputtering device, whereas for each target 1, there is one magnetic base 2 and two magnetic conductors being arranged and functioned correspondingly in a manner the same as the one shown in the first embodiment.

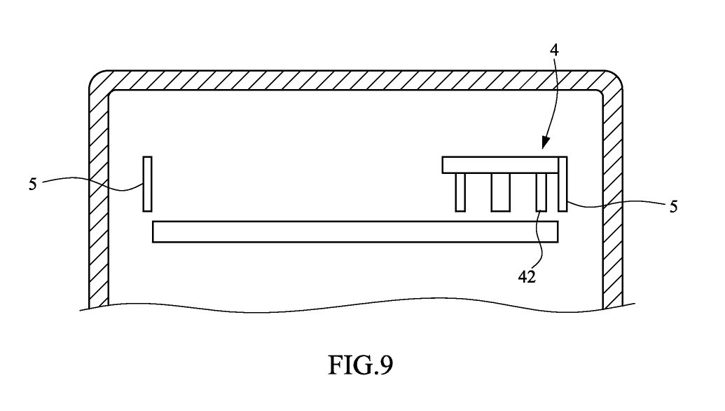

Please refer to FIG. 9, which is a schematic diagram showing a structure for increasing utilization rate of target according to a second embodiment of the present disclosure. In FIG. 9, the magnetic conductors 5 are arranged at locations respectively adjacent to the outer sides of the adjacent second polarity magnetic elements 42 at the time when the magnetic base 4 reaches its two motion limits, i.e. each magnetic conductor 4 is arranged at a position contacting with the outside of the magnetic base 4 when the magnetic base 4 reaches one of its corresponding motion limit, by that the whole structure of the second embodiment is capable of functioning exactly the same as the first embodiment.

The disclosure being thus described, it will be obvious that the same may be varied in many ways. Such variations are not to be regarded as a departure from the spirit and scope of the disclosure, and all such modifications as would be obvious to one skilled in the art are intended to be included within the scope of the following claims.

What is claimed is:

1. A structure for increasing utilization rate of target, comprising:
a magnetic base, capable of moving relative to a target in a reciprocating manner; and
two magnetic conductors, disposed respectively at two motion limits with respect to the reciprocating range of the magnetic base.

2. The structure of claim 1, wherein the magnetic base further comprises:
a frame, configured with a first polarity magnetic element and a plurality of second polarity magnetic elements in a manner that the first polarity magnetic element is arranged at the center of the frame on the side thereof facing toward the target while arranging the second polarity magnetic elements surrounding the first polarity magnetic element in a ring-like formation.

3. The structure of claim 2, wherein the magnetic base further comprises:
a support seat, provided for fixing the first polarity magnetic element and the second polarity magnetic elements.

4. The structure of claim 3, wherein the support seat is made of a non-magnetic conductive material.

5. The structure of claim 2, wherein the first polarity magnetic element as well as each second polarity magnetic element is made up of permanent magnets.

6. The structure of claim 2, wherein the frame is a rectangle-shaped object made of a magnetic conductive material.

7. The structure of claim 2, wherein the two magnetic conductors are arranged at locations respectively between the target and a position under the outer sides the adjacent second polarity magnetic elements at the time when the magnetic base reaches its two motion limits.

8. The structure of claim 2, wherein the magnetic conductors are arranged at locations respectively adjacent to the outer sides of the adjacent second polarity magnetic elements at the time when the magnetic base reaches its two motion limits.

9. The structure of claim 1, wherein each magnetic conductor is made of a material selected from the group consisting of: iron, cobalt, nickel and the alloys thereof.

10. The structure of claim 1, capable of being adapted for a single-target magnetron sputtering device.

11. The structure of claim 1, capable of being adapted for a multiple-target magnetron sputtering device.
